(19) United States
(12) Patent Application Publication
(10) Pub. No.: US 2025/0197433 A1
(43) Pub. Date: Jun. 19, 2025

(54) NOVEL ORGANOPLATINUM COMPOUND, METHOD FOR MANUFACTURING SAME, METHOD FOR MANUFACTURING THIN FILM USING SAME, AND METHOD FOR MANUFACTURING HIGH-PERFORMANCE OPTICAL SENSOR FOR DETECTING MID-INFRARED RAYS USING SAME

(71) Applicant: KOREA RESEARCH INSTITUTE OF CHEMICAL TECHNOLOGY, Daejeon (KR)

(72) Inventors: Chang Gyoun KIM, Daejeon (KR); Hee Soo SO, Daejeon (KR); Taek Mo CHUNG, Daejeon (KR); Jongsun LIM, Daejeon (KR); Bo Keun PARK, Daejeon (KR); Sung MYUNG, Daejeon (KR); Wooseok SONG, Daejeon (KR); Da Som SONG, Daejeon (KR); Sunyoung SHIN, Daejeon (KR); Chae Eun LEE, Daejeon (KR)

(73) Assignee: KOREA RESEARCH INSTITUTE OF CHEMICAL TECHNOLOGY, Daejeon (KR)

(21) Appl. No.: 18/730,146

(22) PCT Filed: Feb. 14, 2023
(86) PCT No.: PCT/KR2023/002125

§ 371 Date: Jul. 18, 2024

(30) Foreign Application Priority Data
Feb. 16, 2022 (KR) 10-2022-0020155

(51) Int. Cl. C07F 15/00; C23C 16/02; C23C 16/30; C23C 16/448; C23C 16/455

(52) U.S. Cl. CPC C07F 15/0093; C23C 16/02; C23C 16/305; C23C 16/4485; C23C 16/45553; C23C 16/45555

(57) ABSTRACT

The present invention relates to a platinum organometallic compound, a method for manufacturing same, a method for manufacturing a thin film using same, and a method for manufacturing a high-performance optical sensor for detecting mid-infrared rays using same.

### TECHNICAL FIELD

The present disclosure relates to a novel organoplatinum compound, a manufacturing method therefor, a method for fabricating thin films for using same, and a method manufacturing a high-performance optical sensor for mid-infrared detection using same. More specifically, the present disclosure relates to an organoplatinum compound, a method for manufacturing the same, a method for fabricating a thin film through chemical vapor deposition or solution processes, and a method for manufacturing a high-performance optical sensor for mid-infrared detection using same, wherein the organoplatinum compound exhibits improved thermal stability and volatility, enabling the easy production of high-quality platinum metal thin films, platinum oxide thin films, or platinum sulfide thin films at low temperatures.

### BACKGROUND ART

Transition metal dichalcogenides are compounds where various transition metals combine with group 16 chalcogen elements (excluding oxygen), such as sulfur(S), selenium (Se), and tellurium (Te). Unlike graphene, which is a representative two-dimensional material with a single structure, transition metal dichalcogenides are next-generation nanomaterials that have multiple structures and exhibit changes in electrical properties into conductors, semiconductors, or insulators due to phase transitions.

Transition metal dichalcogenides, as two-dimensional materials with atomic-layer thickness, exhibit carrier transport characteristics that are very different from those of conventional thin films or bulk materials due to the two-dimensional interactions of their constituent atoms, which results in expected properties such as high mobility, high speed, and low power consumption. Additionally, the transparent and flexible characteristics of transition metal dichalcogenides are highly advantageous for the requirements for semiconductor devices including a few nanometers for semiconductor layer thickness as well as high motility and low power consumption for semiconductor devices. Furthermore, materials that exhibit indirect transition properties in bulk or conventional thin film states demonstrate direct transition properties and excellent photoreactivity when fabricated as monolayers or few-layer structures, and thus are expected to find promising applications in optoelectronic devices.

Transition metal dichalcogenides are typically produced using transition metal precursors and chalcogen precursors, with processes such as Chemical Vapor Deposition (CVD) or Atomic Layer Deposition (ALD) being employed. When a metal thin film is fabricated using a CVD or ALD process, the deposition characteristics and control depend on the properties of the metal precursor, necessitating the development of metal precursors with improved characteristics.

However, transition metal oxides generally require high processing temperatures due to their high boiling points and vapor pressures when used as metal precursors. These high temperatures limit the choice of substrates available for growth, restrict the use of flexible substrates, and hinder compatibility with other low-temperature industrial manufacturing techniques.

Additionally, conventional methods for producing transition 1 dichalcogenide layered materials involve vaporizing suitable transition metal precursors and sulfur or selenium powders for sulfurization or selenization. This approach has drawbacks, such as difficulty in producing uniform thin films over large areas and the potential need for post-processing with sulfur or selenium powders to achieve chalcogenization.

Therefore, there is a need for the development of novel transition metal dichalcogenide precursors that enable processing at lower temperatures, the production of uniform thin films over large areas, and the fabrication of uniform large-area transition metal dichalcogenide thin films without the need for post-processing with chalcogen elements.

Recently, there have been attempts to fabricate transition metal dichalcogenide thin films in which chalcogen elements are introduced into the precursor itself, which includes metal sources, rather than separate simultaneous or sequential introduction of chalcogen elements(S), to prepare precursors bearing transition metal components and chalcogen components in a single precursor molecule, and these precursors are fabricated into transition metal chalcogen thin films through solution processing or vapor deposition processes.

In other words, by introducing chalcogen elements as ligands within the metal precursor, it is possible to form uniform thin films more conveniently without the need for separate addition of chalcogen elements such as sulfur or selenium during the transition metal dichalcogenide thin film manufacturing process.

Regarding the formation of platinum chalcogen thin films among these transition metal dichalcogenide thin films, reference can be made to Korean Patent No. 10-1686386 (issued on Dec. 13, 2016) that discloses a process for producing very thin platinum films by supplying the metal precursor [(1, 2, 5, 6-η)-1,5-hexadiene] dimethylplatinum(II) (HDMP) and oxygen gas at temperatures below 100° C. using an atomic layer deposition process. Additionally, Korean Patent Publication No. 10-2010-0109567 (issued on Oct. 8, 2010) discloses a metal (platinum) precursor containing a beta-diketiminato group as a ligand and a method for producing metal thin films or metal oxide thin films using this precursor. However, these methods cannot directly form metal chalcogen thin films alone and require improvements in terms of thermal stability, chemical reactivity, and volatility.

As described above, transition metal dichalcogenide thin films are highly photoreactive and expected to be useful as optoelectronic devices or optical sensors. However, there has been little attempt to produce optical sensors using platinum chalcogen thin films, especially sensors with improved optical properties in the mid-infrared region.

Therefore, there is a need to develop novel organoplatinum compounds with improved thermal stability and volatility, enabling the easy production of platinum thin films, platinum oxide thin films, or platinum sulfide thin films at lower temperatures. Furthermore, there is also a need to develop improved thin film manufacturing processes and high-performance optical sensors with enhanced optical properties in the mid-infrared region by easily producing uniform large-area platinum sulfide thin at lower temperatures.

### DISCLOSURE

### Technical Problem

The present disclosure primarily aims to provide a novel organoplatinum compound as a precursor that exhibits improved thermal stability and volatility, allowing for the easy production of platinum thin films, platinum oxide thin films, or platinum sulfide thin films at lower temperatures.

Also, the present disclosure aims to provide a novel method for manufacturing the organoplatinum compound.

In addition, the present disclosure is to provide a method for fabricating platinum thin films, platinum oxide thin films, or platinum sulfide thin films using the organoplatinum compound as a precursor.

Furthermore, the present disclosure is to provide a method for manufacturing high-performance optical sensors with improved optical properties in the mid-infrared region, using the precursor that allows for easy production of large-area platinum sulfide thin films at lower temperatures.

Moreover, the present disclosure is to provide a high-performance optical sensor for mid-infrared detection, manufactured by the optical sensor manufacturing method.

### Technical Solution

To achieve the technical aims, the present disclosure provides an organometallic compound represented by the following Chemical Formula A-1 or A-2:

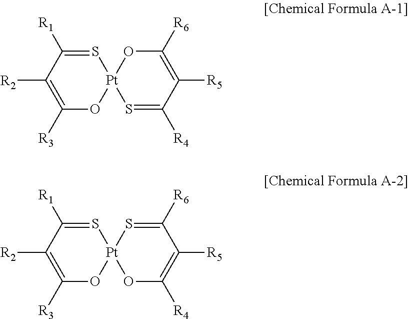

wherein,
R₁, R₃, R₄, and R₆, which are same or different, are each independently any one selected from a linear, branched, or cyclic alkyl of C1-C10 and a linear, branched, or cyclic halogenated alkyl of C1-C10;
R₂ and R₅, which same or different, are each independently any one selected from a hydrogen atom, a deuterium atom, a linear, branched, or cyclic alkyl of C1-C10, and a linear, branched, or cyclic halogenated alkyl of C1-C10.

The present disclosure also provides a method for fabricating a platinum thin film, a platinum oxide thin film, or a platinum sulfide thin film using the organometallic compound represented by Chemical Formula A-1 or A-2 as a metal precursor.

Furthermore, the present disclosure provides a method for manufacturing an organometallic compound represented by Chemical Formula A-1 or A-2 using the halogenated platinum compound represented by the following Compound D, the ketone compound represented by the following Compound C1, and the ketone compound represented by the following Compound C2 as reactants:

PtX₁X₂ [Compound D]

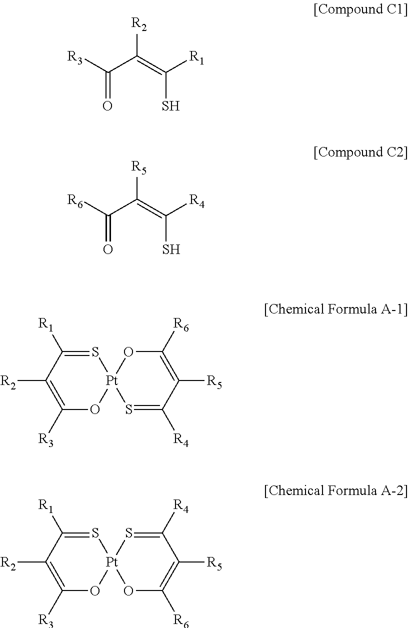

wherein,
X₁ and X₂ in Compound D are same or different and each independently any one halogen element selected from F, Cl, Br, and I,
R₁ to R₆ in Compounds C1 and C2 and Chemical Formulas A-1 and A-2 are as defined above.

Additionally, the present disclosure provides a method for manufacturing an optical sensor, the method including the steps of: a) introducing into a deposition chamber a substrate on which a platinum sulfide thin film is to be formed; b) forming a platinum sulfide thin film on the substrate in the chamber by chemical vapor deposition or atomic layer deposition using a single-source precursor that bears both sulfur(S) and platinum (Pt) elements within a single molecule, where the platinum atom functions as a central metal and the sulfur atom is directly bonded to the platinum; and c) forming a metal electrode in direct contact with the formed platinum sulfide thin film.

In an embodiment, the single-source precursor used in step b) may include an organometallic compound represented by Chemical Formula A-1, A-2, or B:

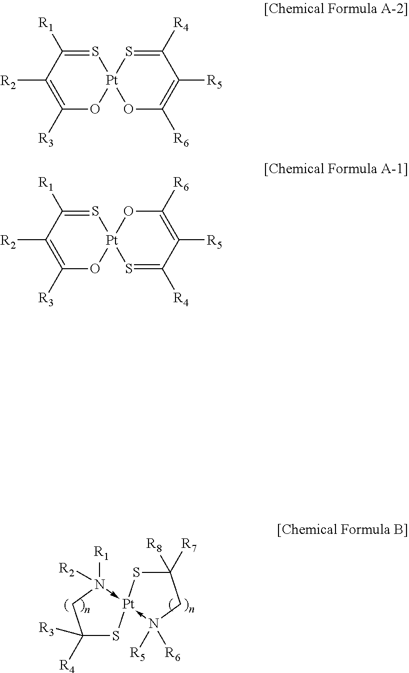

in Chemical Formulas A-1 and A-2,
R₁, R₃, R₄, and R₆, which are same or different, are each independently any one selected from a linear, branched, or cyclic alkyl of C1-C10 and a linear, branched, or cyclic halogenated alkyl of C1-C10, and
R₂ and R₅, which are same or different, are each independently any one selected from a hydrogen atom, a deuterium atom, a linear, branched, or cyclic alkyl of C1-C10, and a linear, branched, or cyclic halogenated alkyl of C1-C10; and
in Chemical Formula B,
R₁ to R₈, which are same or different, are each independently any one selected from a hydrogen atom, a deuterium atom, a linear, branched, or cyclic alkyl of C1-C10, and a linear, branched, or cyclic halogenated alkyl of C1-C10, and
n is an integer of 1 to 3.

The present disclosure also provides a high-performance optical sensor for mid-infrared detection manufactured by the method described above.

### Advantageous Effects

Exhibiting improved thermal stability and volatility, the organometallic compounds represented by Chemical Formula A-1 or A-2 in the present disclosure are suitable as precursors for fabricating platinum thin films, platinum oxide thin films, or platinum sulfide thin films. When used, the organometallic compounds allow the formation of large-area or uniform thin films. Additionally, since the precursor bears sulfur(S), it facilitates the fabrication of platinum chalcogenide films (PtS₂) without the need for an additional sulfur(S) introduction step during the fabrication of the platinum sulfide thin film.

Furthermore, the optical sensors manufactured according to the present disclosure exhibit improved optical properties not only in the visible spectrum but also in the mid-infrared region as the platinum sulfide thin film can be easily fabricated at lower temperatures to have a large area with a high-quality uniform surface.

In particular, the inclusion of sulfur(S) in the precursor manufacturing platinum sulfide thin films eliminates the need for additional steps to introduce chalcogen elements.

### DESCRIPTION OF DRAWINGS

FIG. 1 shows the TGA curves of the Pt(dpmS)₂ compounds and the Pt(dmampS)₂ compounds prepared according to Preparation Examples 1 and 2, respectively.

FIG. 2 is a schematic diagram of the thin film formation apparatus used in the chemical vapor deposition method for forming platinum sulfide thin films according to the present disclosure.

FIG. 3 shows the results of electron microscopy, Raman spectroscopy, and X-ray photoelectron spectroscopy performed on the platinum sulfide thin films according to the present disclosure.

FIG. 4 shows the optical properties of the optical sensor according to the present disclosure in the visible (532 nm) and near-infrared (1064 nm) regions.

FIG. 5 shows the optical properties of the optical sensor in the mid-infrared region according to the present disclosure.

### MODE FOR INVENTION

Hereinafter, a detailed description will be given of the present disclosure. Unless otherwise defined, all technical and scientific terms used herein have the same meaning as commonly understood by one of ordinary skill in the art to which this disclosure belongs. Generally, the nomenclature used herein is well known and commonly employed in the art.

Throughout the specification, when a part is described as “comprising” or “including” a component, the term will be understood to imply the inclusion of stated elements but not the exclusion of any other elements unless otherwise stated.

Leading to the present disclosure, intensive and thorough research conducted by the present inventors, with the aim of fabricating platinum thin films with excellent properties, resulted in the finding that an organometallic platinum compound, in which dehydrogenated ligands of sulfur(S)-bearing ketone compounds represented by Compound C1 and Compound C2 are coordinated to a platinum atom (Pt), can be used as a precursor for fabricating platinum thin films, platinum oxide thin films, or platinum sulfide thin films.

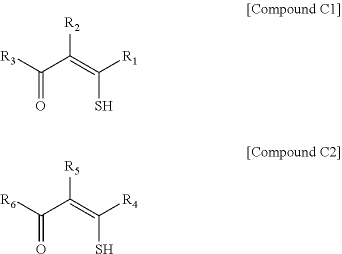

Specifically, the organometallic compound represented by Chemical Formula A-1 or A-2 include two ligands with identical or different structures, each containing a sulfur(S) atom and an oxygen atom from a carbonyl group which are both coordinated to a platinum atom, and thus provides high volatility, excellent chemical and thermal stability, and a rapid deposition rate of thin films at relatively low temperatures. Additionally, with the introduction of the chalcogen element sulfur(S) thereinto, the precursor containing the transition metal source can be useful for fabricating transition metal chalcogenide thin films.

In the present disclosure, the organometallic compounds represented by Chemical Formula A-1 or A-2 bearing sulfur(S) as a chalcogen element within the precursor itself enable the formation of sulfur chalcogenide thin films without the need for separate or sequential introduction of the chalcogen element(S) along with the metal precursor.

Furthermore, to achieve the technical subjects mentioned above, large-area, the present disclosure provides an optical sensor with improved optical properties not only in the visible spectrum but also in the mid-infrared region. In this regard, it was found that uniform platinum sulfide thin films can be fabricated at low temperature on a substrate in a chamber by a chemical vapor deposition or atomic layer deposition method using a single-source precursor bearing both sulfur(S) and platinum (Pt) elements, and the films allow for the manufacture of the optical sensors.

Below, the present disclosure will be described in greater detail.

The present disclosure provides an organometallic compound bearing platinum (Pt) represented by Chemical Formula A-1 or A-2.

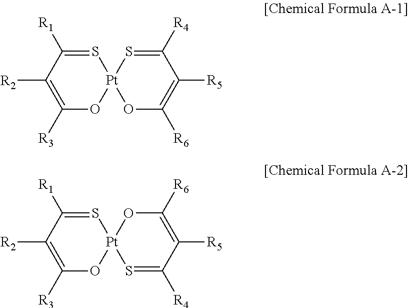

wherein,
R₁, R₃, R₄, and R₆, which are same or different, are each independently any one selected from a linear, branched, or cyclic alkyl of C1-C10 and a linear, branched, or cyclic halogenated alkyl of C1-C10, and
R₂ and R₅, which are same or different, are each independently any one selected from a hydrogen atom, a deuterium atom, a linear, branched, or cyclic alkyl of C1-C10, and a linear, branched, or cyclic halogenated alkyl of C1-C10.

Here, the organometallic compounds represented by Chemical Formula A-1 or A-2 has two identical or different monovalent anionic ligands including a monothiol beta-diketone ligand containing R₁ to R₃ and a monothiol beta-diketone ligand containing R₄ to R₆, each being coordinated to the central atom (platinum), and can exhibit thermal stability and good volatility, thus finding applications as a precursor for metal thin films, metal oxide thin films, or metal sulfide thin films.

Additionally, as described in the foregoing, when the precursor complex with the chalcogen element sulfur(S) coordinated to the transition metal therein is used as a precursor for fabricating metal sulfide thin films (platinum disulfide films or platinum sulfide films) as transition metal chalcogen thin films, the sulfur(S) atom contained within the complex itself can be used as a chalcogen(S) source.

Moreover, in the organometallic compounds represented by Chemical Formula A-1 or A-2 according to the present disclosure, the substituents R₁, R₃, R₄, and R₆ in the monothio beta-diketone ligand, which are same or different, may each be independently any one selected a linear, branched, or cyclic alkyl of C1-C10, and a linear, branched, or cyclic halogenated alkyl of C1-C10, and more preferably, the substituents R₁, R₃, R₄, and R₆, which are same or different, may each be independently a branched or cyclic alkyl of C1-C6, and more preferably, R₁, R₃, R₄, and R₆, which are same or different, may each be independently any one selected from CH₃, C₂H₅, CH(CH₃)₂, and C(CH₃)₃. In this regard, the organometallic compounds represented by Chemical Formula A-1 or A-2 have improved volatility and excellent thermal stability due to the low molecular weight thereof.

Furthermore, the substituents R₂ and R₅ in the monothio beta-diketone ligand of the organometallic compounds represented by Chemical Formula A-1 or A-2 according to the present disclosure, which are same or different, are each independently any one selected from a hydrogen atom, a deuterium atom, CH₃, and C₂H₅. In this regard, as described in the foregoing, an improvement can be brought about in volatility and thermal stability, making the compounds particularly suitable as precursors for chemical vapor deposition (CVD) or atomic layer deposition (ALD) due to their volatility characteristics.

In a more preferred embodiment of the present disclosure, the substituents Ry and R₅, which are same or different, may each be independently any one selected from a hydrogen atom, a deuterium atom, CH₃, and C₂H₅, and the substituents R₁, R₃, R₄, and R₆, which are same or different, may be each independently any one selected from CH₃, C₂H₅, CH(CH₃)₂, and C(CH₃)₃.

In another preferred embodiment of the present disclosure, the monothio beta-diketone ligand containing R₁ to R₃ and the monothio beta-diketone ligand containing R₄ to R₆ may be identical to each other.

The present disclosure also provides a method fabricating a platinum thin film, a platinum oxide thin film, or a platinum sulfide thin film using the organometallic compound represented by Chemical Formula A-1 or A-2 as a metal precursor. This method may be performed by chemical vapor deposition (CVD), atomic layer deposition (ALD), or solution processes in which a solution of the precursor in a solvent is applied. When using the organometallic compounds represented by Chemical Formula A-1 or A-2 as metal precursors to fabricate platinum sulfide thin films, the platinum sulfide thin films may include platinum dichalcogenide compounds (platinum disulfide (PtS₂) and platinum sulfide (PtS)).

Additionally, the present disclosure provides a composition for fabricating a platinum thin film, a platinum oxide thin film, or a platinum sulfide thin film including the organometallic compound represented by Chemical Formula A-1 or A-2.

For example, the composition may use a mixture of one or more compounds represented by Chemical Formula A-1 or A-2. The composition may be mixed with an organic solvent or used in the absence of an organic solvent, and may be used for thin film formation using chemical vapor deposition (CVD) methods, atomic layer deposition (ALD) methods, or solution processes where the precursor is dissolved in a solvent and coated.

In this context, the CVD method, ALD method, or solution process can be adjusted according to the respective process conditions to control the growth rate and formation temperature of the thin film, thereby producing a thin film with optimal thickness and density.

More specifically, when using the CVD method, a reactant including the organometallic precursor of the present disclosure is supplied in gaseous form to a reactor containing a substrate of various types or shapes, thereby forming a platinum thin film, platinum oxide thin film, or platinum sulfide thin film on the substrate. In this case, since the organometallic compounds represented by Chemical Formula A-1 or A-2 of the present disclosure are thermally stable and highly volatile, they can be used to produce platinum thin films, platinum oxide thin films, or platinum sulfide thin films in desired forms under various conditions.

Additionally, when using the ALD method in the present disclosure, the reactant including the organometallic compound represented by Chemical Formula A-1 or A-2 is supplied to the deposition chamber in pulses to cause a chemical reaction with the wafer surface, thus forming precise monolayer films.

Furthermore, when forming thin films using a solution process in the present disclosure, the organometallic compound (precursor) represented by Chemical Formula A-1 or A-2 is dissolved in a solvent and then coated onto the substrate, followed by heating or applying external energy to form platinum thin films, platinum oxide thin films, or platinum chalcogenide (sulfide) thin films. Preferably, the organometallic compounds represented by Chemical Formula A-1 or A-2 contain both platinum and chalcogen elements within a single molecule. These compounds have good solubility in organic solvents such as tetrahydrofuran (THF), diethyl ether, hexane, toluene, benzene, dimethylformamide (DMF), and acetone. This advantageously allows for the easy formation of platinum chalcogenide thin films without the need for additional chalcogen element (sulfur) input during the solution process.

The present disclosure provides a method for manufacturing an organometallic compound represented by Chemical Formula A-1 or A-2, wherein a halogenated platinum compound represented by Compound D, a ketone compound represented by Compound C1, and a ketone compound represented by Compound C2 as reactants.

PtX₁X₂ [Compound D]

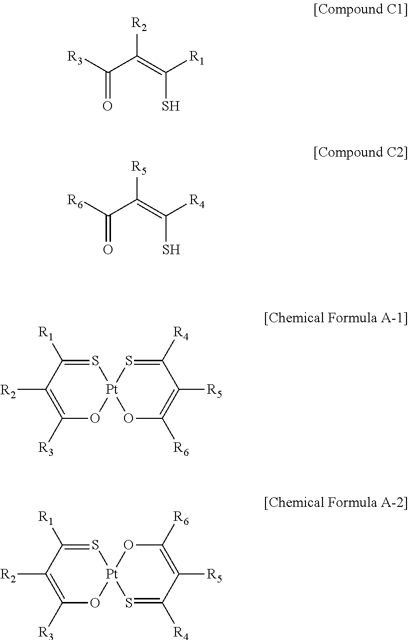

in Compound D,
X₁ and X₂, which are same or different, are each independently a halogen element selected from F, Cl, Br, and I, and
R₁ to R₆ in Compound D, Compound C1, Compound C2, Chemical Formula A-1, and Chemical Formula A-2 are each as defined above.

Specifically, the organometallic compounds represented by Chemical Formula A-1 or A-2 are synthesized by using the organometallic compound represented by Compound D, the ketone compound represented by Compound C1, and the ketone compound represented by Compound C2 as reactants. The ketone compounds represented by Compound C1 and Compound C2 are converted into monovalent anions by deprotonation. The monovalent anions are then reacted with Compound D to cause the halogen elements in Compound D to leave and be substituted with the monothio beta-diketone ligand containing R₁ to R₃ and the monothio beta-diketone ligand containing R₄ to R₆, forming coordinated bonds between the ligands and the platinum atom. As a result, the organometallic compounds represented by Chemical Formula A-1 or A-2 are formed.

In the ketone compounds represented by Compound C1 and Compound C2 used in the present disclosure, R₂ and R₅, which are same or different, may each be preferably any one selected from a hydrogen atom, a deuterium atom, CH₃, and C₂H₅, and R₁, R₃, R₄, and R₆, which are same or different, may each be independently a branched or cyclic alkyl of C1-C6, and more preferably each be at least one selected from CH₃, C₂H₅, CH(CH₃)₂ and C(CH₃)₃.

In a more preferred embodiment of the present disclosure, the ketone compounds represented by Compound C1, containing substituents R₁ to R₃, and the ketone compounds represented by Compound C2, containing substituents R₄ to R₆, may be identical to each other.

In the synthesis of the organometallic compounds represented by Chemical Formula A-1 or A-2, the deprotonation reactions of the ketone compounds represented by Compound C1 and Compound C2, and their subsequent reaction with the organometallic compound represented by Compound D may involve the use of organic solvents. Examples of suitable organic solvents include toluene, tetrahydrofuran, hexane, cyclohexane, diethyl ether, acetonitrile, and dimethylformamide with preference for tetrahydrofuran, but are not limited thereto.

The reaction may be preferably carried out in the organic solvent at a temperature range of 0 to 100° C. and more preferably 10 to 40° C., for 12 to 24 hours to produce the compounds represented by Chemical Formula A-1 or A-2.

To separate the product from by-products or unreacted materials, techniques such as sublimation, distillation, extraction, or column chromatography may be used, yielding a high-purity organometallic compound.

The resulting high-purity organometallic compounds represented by Chemical Formula A-1 or A-2 may be solid or liquid at room temperature, exhibiting thermal stability and good volatility.

Additionally, the present disclosure provides a novel method for manufacturing an optical sensor that includes the platinum sulfide thin film formed using a single-source precursor.

More specifically, the method for manufacturing an optical sensor according to the present disclosure includes the steps of: a) introducing a substrate into a deposition chamber where a platinum sulfide thin film is to be formed; b) forming a single-source precursor bearing both sulfur(S) and platinum (Pt) elements within a single molecule into a platinum sulfide thin film by chemical vapor deposition (CVD) or atomic layer deposition (ALD) on the substrate in the chamber, wherein the sulfur atom is directly bonded to the platinum atom; and c) forming a metal electrode in direct contact with the formed platinum sulfide thin film.

The single-source precursor in the present disclosure refers to a precursor that contains all the necessary components for the thin film within a single precursor molecule, used alone without additional precursors, during thin film formation by CVD, ALD, or solution processing.

For example, in forming metal chalcogenide thin films, traditional techniques involve using separate metal and chalcogen precursors during CVD or ALD. In contrast, the single-source precursor that contains both metal and chalcogen components can be used alone for the formation of metal chalcogenide thin films.

So long as it allows for manufacturing optical sensors with a platinum sulfide thin film, any substrate on which the platinum sulfide thin film is to be fabricated may be used in step a) of the present disclosure. The substrate may be made of any one selected from silicon (Si), SiO₂, SiO₂/Si, sapphire, glass, quartz, flexible glass (Willow glass), and plastics. Examples of the plastics include, but are not limited to, polyethylene terephthalate (PET) and polyimide (PI).

Additionally, the method may further include a step of subjecting the substrate to hydrophilic treatment before step a). This treatment may be selected from UV light treatment, plasma treatment, or discharge treatment, allowing the single-source precursor compound to coat uniformly over the entire substrate surface.

Step b) of forming a platinum sulfide thin film corresponds to a step of forming a platinum sulfide thin film from the single source precursor of step a) on the substrate in the deposition chamber by chemical vapor deposition or atomic layer deposition.

When using the chemical vapor deposition method, the single-source precursor or a reactant containing same is supplied in gaseous form to a deposition chamber (reactor) which may contain various types or shapes of substrates therein, forming the platinum sulfide thin film on the substrate. When using the atomic layer deposition (ALD) method, the single-source precursor or a reactant containing same is supplied in gaseous form to the deposition chamber in pulses, causing a chemical reaction with the wafer surface and forming a precise monolayer film.

The CVD or ALD processes can be adjusted to control growth rate and deposition temperature conditions of the thin film, achieving an optimal thickness and density.

The platinum sulfide thin film formed in step b) may have a thickness of 5 nm to 0. 5 μm, preferably from 10 nm to 0. 2 μm, and more preferably from 20 nm to 0. 1 μm.

Additionally, the platinum sulfide thin film layer in the present disclosure corresponds to a two-dimensional transition metal chalcogenide layer where a platinum atom is covalently bonded to a sulfur atom. This layer can include at least one component selected from PtS, PtS₂, and mixtures thereof. Preferably, the layer may include PtS₂, and more preferably, PtS₂ as the main component. Here, “PtS₂ as the main component” means that PtS₁ constitutes 30 wt % or more, preferably 40 wt % or more, more preferably 50 wt % or more, even more preferably 60 wt % or more, most preferably 70 wt % or more, and ideally 80 wt % or more, and even more ideally 90% or more of the total weight of the platinum sulfide layer.

The shape of the external surface of the platinum sulfide layer may be selected from circular, oval, or rectangular. The size may vary depending on the size of the thin film forming equipment, but the thin film may be made to have a large area preferably with a circular or rectangular shape.

Furthermore, in step b) of the present disclosure, the single-source precursor may undergo sublimation or evaporation within the deposition chamber containing the substrate, or sublimation or evaporation may occur in a separate chamber, with the vapor or gas being transferred to the deposition chamber containing the substrate.

Specifically, the single-source precursor is placed in a crucible or evaporation mechanism capable of being heated within the deposition chamber containing the substrate. The precursor is then evaporated or sublimated by heating, and the vaporized or gaseous state precursor is introduced onto the substrate within the deposition chamber. Alternatively, the precursor can be sublimated or evaporated in a separate chamber or heating apparatus, and the vaporized or gaseous precursor can be transferred via transfer tubes or pipes to the substrate within the deposition chamber. This process can be selected based on the deposition environment or thin film formation conditions as deemed appropriate by the operator.

The single-source precursor used for forming the platinum sulfide thin film in the present disclosure includes both sulfur (S) and platinum (Pt) components within a single molecule. The single-source precursor includes a platinum complex where the sulfur atom is directly bonded to the platinum atom. Preferably, single-source precursor includes a platinum complex with 1 to 4 sulfur atoms directly bonded to the platinum atom within the molecule.

In an embodiment, the single-source precursor used in step b) may include a platinum complex where at least one sulfur atom is directly bonded to the platinum, as described previously. More preferably, the single-source precursor may include an organometallic compound represented by any one of Chemical Formulas A-1, A-2, and B.

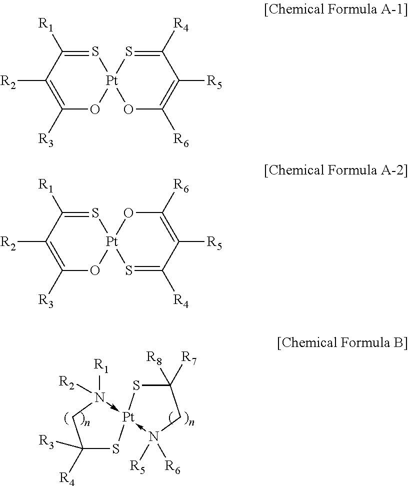

In Chemical Formula A-1 and Chemical Formula A-2,
R₁, R₃, R₄, and R₆, which are same or different, are each independently any one selected from linear, branched, or cyclic alkyl groups of C1-C10 and linear, branched, or cyclic halogenated alkyl groups of C1-C10, and
R₂ and R₅, which are same or different, are each independently any one selected from a hydrogen atom, a deuterium atom, a linear, branched, or cyclic alkyl of C1-C10, and a linear, branched, or cyclic halogenated alkyl of C1-C10, and
in Chemical Formula B,
R₁ to R₈, which are same or different, are each independently any one selected from a hydrogen atom, a deuterium atom, a linear, branched, or cyclic alkyl of C1-C10, and a linear, branched, or cyclic halogenated alkyl of C1-C10, and
n is an integer of 1 and 3.

Here, the organometallic compound represented by Chemical Formula A-1 or A-2 has two identical or different monovalent anionic ligands including a monothiol beta-diketone ligand containing R₁ to R₃ and a monothiol beta-diketone ligand containing R₄ to R₆, each being coordinated to the central atom (platinum), and can exhibit thermal stability and good volatility, thus finding applications as a precursor for metal thin films, metal oxide thin films, or metal sulfide thin films. The organometallic compound represented by Chemical Formula B has two identical or different monovalent anionic ligands including an aminothiol ligand containing R₁ to R₄ and an aminothiol ligand containing R₅ to R₈, each being coordinated to the central atom (platinum), and can exhibit thermal stability and good volatility, thus finding applications as a precursor for metal sulfide thin films.

As described above, the precursor in the present disclosure contains a chalcogen element, sulfur(S), within the complex itself, coordinated to the transition metal. When used as a precursor for forming transition metal chalcogenide thin films (platinum disulfide or platinum sulfide thin films), the sulfur(S) within the complex serves as the chalcogen source, allowing the formation of metal chalcogenide thin films without the need for simultaneous or sequential addition of a separate chalcogen element(S).

Moreover, in the organometallic compounds represented by Chemical Formula A-1 or A-2 according to the present disclosure, the substituents R₁, R₃, R₄, and R₆ in the monothio beta-diketone ligand, which are same or different, may each be independently any one selected a linear, branched, or cyclic alkyl of C1-C10, and a linear, branched, or cyclic halogenated alkyl of C1-C10, and more preferably, the substituents R₁, R₃, R₄, and R₆, which are same different, may each be independently a branched or cyclic alkyl of C1-C6, and more preferably, R₁, R₃, R₄, and R₆, which are same or different, may each be independently any one selected from CH₃, C₂H₅, CH(CH₃)₂, and C(CH₃)₃. In this regard, the organometallic compounds represented by Chemical Formula A-1 or A-2 have improved volatility and excellent thermal stability due to the low molecular weight thereof.

Additionally, the substituents R₂ and R₅ in the monothio beta-diketone ligand of Chemical Formula A-1 or A-2 according to the present disclosure, which are same or different, are each independently any one selected from a hydrogen atom, a deuterium atom, CH₃, and C₂H₅. In this regard, as described in foregoing, an improvement can be brought about in the volatility and thermal stability, making the compounds particularly suitable as precursors for chemical vapor deposition (CVD) or atomic layer deposition (ALD) due to their volatility characteristics.

In a more preferred embodiment of the present disclosure, the substituents R₂ and R₅, which are same or different, may each be independently any one selected from a hydrogen atom, a deuterium atom, CH₃, and C₂H₅, and the substituents R₁, R₃, R₄, and R₆, which are same or different, may be each independently any one selected from CH₃, C₂H₅, CH(CH₃)₂, and C(CH₃)₃.

In a preferred embodiment of the present disclosure, the monothio beta-diketone ligand containing substituents R₁ to R₃ and the monothio beta-diketone ligand containing substituents R₄ to R₆ in the organometallic compounds represented by Chemical Formula A-1 or A-2 may be identical to each other.

In a more preferred embodiment of the present disclosure, the substituents R₁ to R₈ in the organometallic compounds represented by Chemical Formula B, which are same or different, are each independently any one selected from a hydrogen atom, a deuterium atom, a linear, branched, or cyclic alkyl of C1-C10, and a linear, branched, or cyclic halogenated alkyl of C1-C10. Preferably, the substituents are same or different and are each independently a branched or cyclic alkyl of C1-C6. More preferably, the substituents are same or different and are each independently any one selected from CH₃, C₂H₅, CH(CH₃)₂, and C(CH₃)₃. In this case, the organometallic compounds represented by Chemical Formula B have improved volatility and excellent thermal stability due to the low molecular weight thereof.

Furthermore, the organometallic compound represented by Chemical Formula B in the present disclosure may be prepared using the halogenated platinum compound represented by the following Compound D, the aminothiol compound represented by the following Compound G1, and the aminothiol compound represented by the following Compound G2 as reactants:

PtX₁X₂ [Compound D]

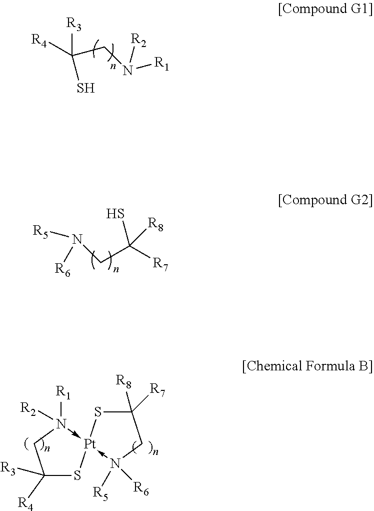

wherein,
X₁ and X₂ in Compound D are same or different and each independently any one halogen element selected from F, Cl, Br, and I, and
n and R₁ to R₆ in Compounds D, G1, and G2, and Chemical Formula B are as defined above.

That is, the organometallic compound represented by Chemical Formula B is synthesized by using the organometallic compound represented by Compound D, the aminothiol compound represented by Compound G1, and the aminothiol compound represented by Compound G2 as reactants. The aminothiol compounds represented by Compound C1 and Compound C2 are converted into monovalent anions by deprotonation. The monovalent anions are then reacted with Compound D to cause the halogen elements in Compound D to leave and be substituted with the monothio beta-diketone ligand containing R₁ to R₄ and the monothio beta-diketone ligand containing R₅ to R₈, forming coordinated bonds between the ligands and the platinum atom. As a result, the organometallic compound represented by Chemical Formula B is formed.

In addition, the substituents R₁ to R₈ in the aminothiol compounds represented by Compounds G1 and G2, which are same or different, may each be independently a branched or cyclic alkyl of C1-C6. More preferably, the substituents, which are same or different, may each be independently any one selected from CH₃, C₂H₅, CH(CH₃)₂, and C(CH₃)₃.

In a more preferred embodiment, the aminothiol compounds represented by Compounds G1 and G2 may be identical to each other.

In addition, the metal electrode formed in step c) of the method for manufacturing an optical sensor according to the present disclosure may be made of a conductive metal such as gold, silver, or copper, either alone or in combination. Moreover, mixed components may be employed to construct a composite structure with a first metal and a second metal surrounding the first metal. The metal electrode may be formed using any one selected from wire, metal powder, metal paste, and a combination thereof, each containing the conductive metal component.

The metal electrode may be provided as a single entity or multiple entities within the sensor. For example, if the sensor includes two metal electrodes, they may be connected to opposite sides of the platinum sulfide layer.

In the case where a single metal electrode is used in the sensor, multiple sensors may be provided, each including a substrate, a platinum sulfide layer, and a metal electrode in contact with one side of the platinum sulfide layer, with the structure wherein one platinum sulfide layer is electrically connected to another.

For example, two sensors, each including a substrate, a platinum sulfide layer, and a metal electrode in contact with the platinum sulfide, e.g., composed of a first sensor including a first substrate, a first platinum sulfide layer, and a first metal electrode, and a second sensor including a second substrate, a second platinum sulfide layer, and a second metal electrode, may have the structure in which the first platinum sulfide layer and the second platinum sulfide layer are connected to each other, thus making the sensors function entirely as a single sensor. In this regard, the first substrate and the second substrate may share the same substrate, or the first and the second platinum sulfide layer may be deposited on respective separate substrates.

To form the metal electrode, methods such as thermal evaporation or metal paste may be used. For example, silver paste (Ag paste) may be used to form electrodes with silver wiring. For forming transition metal wiring with metals such as gold, chromium, or nickel, thermal evaporation using a shadow mask may be employed.

The present disclosure also provides an optical sensor manufactured by the manufacturing method described above. The resulting optical sensor exhibits improved optical properties in the mid-infrared region, offering advantages for mid-infrared detection.

A better understanding of the present disclosure may be obtained via the following examples which are set forth to illustrate, but are not to be construed as limiting the present disclosure.

### Synthesis of Platinum Complex

### <Preparation Example 1> Synthesis of Pt(dpms)2

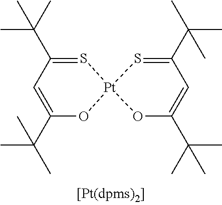

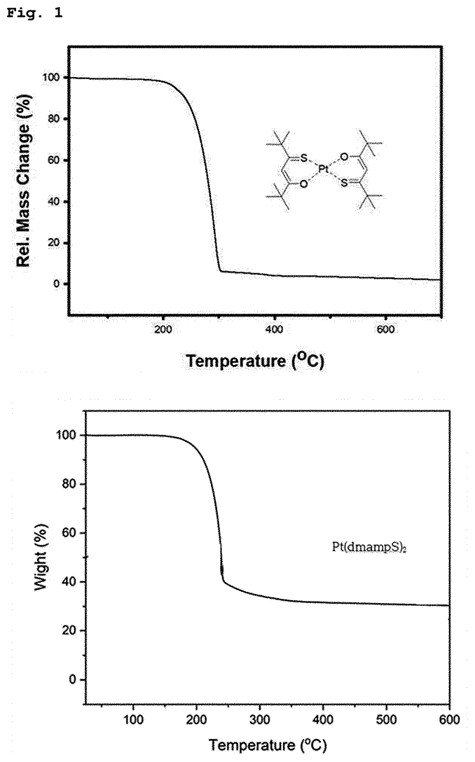

To NaNH₂ (0.097 g, 2. 5 mmol) in THE (10 ml), drops of dpmS (2, 2, 6, 6-tetramethyl-5-thioxo-3-heptanone) (0.5 g, 2.5 mmol) were slowly added. At this time, gas evolved while NaNH₂ completely dissolved. The resulting solution was then slowly added to THE (10 ml) containing PtCl₂ (0.213 g, 1.2 mmol) in a flask and the mixture was allowed to react overnight at room temperature. The olive green PtCl₂, which was initially insoluble in THE, gradually dissolved and turned a reddish color with a slight orange tint. After the reaction, the solvent and by-products were removed under reduced pressure, and subsequent purification through sublimation (0.8 torr, 130° C.) afforded the final complex (0. 25 g, yield 35%). Thermogravimetric analysis (TGA) of the complex showed a weight loss around 300° C. as depicted in FIG. 1.

¹H NMR (500 MHZ, Benzene-d6): δ 6.64 (s, 1H), 1.30 (s, 9H), 1.00 (s, 9H).

¹³C NMR (125 MHZ, Benzene-d6): δ 194.177, 163.871, 112.544, 44.249, 42.882, 31.009, 28.095

Anal. Calc. for C₂₂H₄₄O₂S₂Pt: C, 44.50; H, 6.45; S, 10.80. Found: C, 44.94; H, 6.44; S, 10.46.

### <Preparation Example 2> Synthesis of Pt(dmampS)₂ (dmampS: 1-dimethylamino-2-methyl propane-2-thiolate)

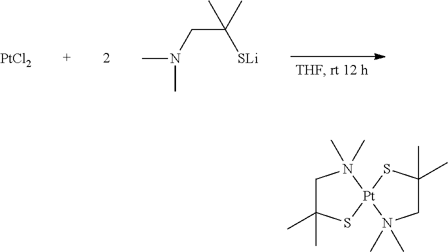

In a Schlenk flask, a solution of PtCl₂ (0. 266 g, 1 mmol) in THE was added with Li (dmampS) (0. 278 g, 2 mmol) and stirred for 12 hours. The reaction mixture was filtered, and the solvent was removed under reduced pressure. The residue was sublimated at 130° C. under a reduced pressure (800 mTorr) to afford the title compound as a yellow solid.

Thermogravimetric analysis (TGA) showed a single weight loss above 180° C., with a final residue of 30%. EI-MS: m/z=459 [Pt(dmampS)₂]⁺

¹H NMR (500 MHZ, Benzene-d6): δ 2. 70 (s, 3H), 2. 20 (s, 1H), 1. 63 (s, 3H).

¹³C NMR (125 MHZ, Benzene-d6): δ 87.59, 57.48, 43.07, 33.16.

EA: Anal. Calcd. (Found) for C₁₂H₂₈N₂S₂Pt: C, 31.36 (31. 92); H, 6.14 (6.15); N, 6.10 (6.06); S, 13.95 (14.01).

### Evaluation of Platinum Complex Properties and Thin Film Fabrication

### Example 1. Analysis of Thermal Properties of Platinum Complexes

Evaluation was made of the potential of the platinum complexes (precursors) synthesized in Preparation Examples 1 and 2 as precursors for thin film formation. To this end, thermogravimetric analysis (TGA) was performed to measure the thermal stability and decomposition temperatures f the platinum complexes.

In the TGA method, the products were heated at a rate of 10° C./min up to 800° C. while nitrogen gas was introduced at a pressure of 1.5 bar/min. The TGA curves of the platinum precursor compounds synthesized in Preparation Examples 1 and 2 are depicted in FIG. 1.

As can be seen in FIG. 1, the platinum precursor compound from Preparation Example 1 exhibited a 94% mass loss in the temperature range from 200° C. to 300° C., followed by an additional 3% mass loss in the subsequent temperature range from 300° C. to 400° C. The platinum precursor compound volatilized in the mass loss interval, leaving a final residue of 3%. The platinum precursor compound from Preparation Example 2 exhibited a 70% mass loss in the temperature range from 200° C. to 300° C., with a final residue of approximately 30% remaining after the mass loss interval.

Therefore, the organometallic compounds represented by Chemical Formulas A-1, A-2, and B of the present disclosure were observed to possess favorable properties for forming platinum thin films, platinum oxide thin films, or platinum sulfide thin films, as analyzed by TGA.

### Example 2. Thin Film Formation Using Chemical Vapor Deposition and Analysis for Thin Film Properties

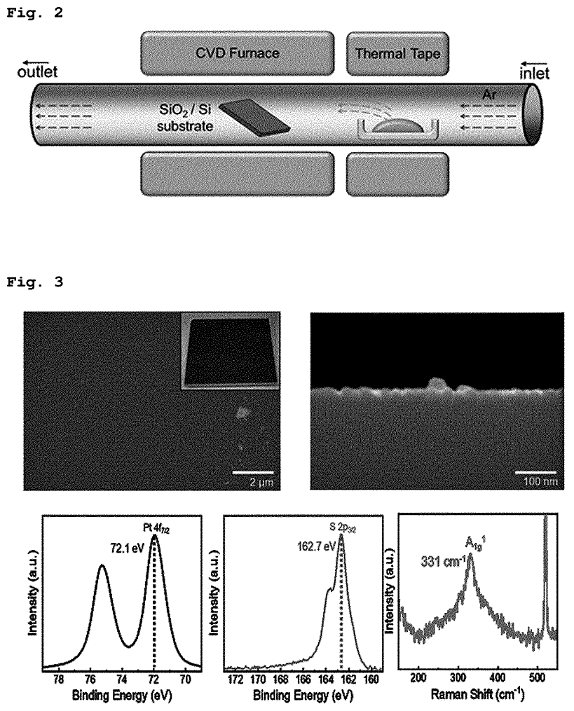

FIG. 2 is a schematic diagram of a thin film formation apparatus used in the chemical vapor deposition method for forming platinum sulfide thin films according to the present disclosure. By chemical vapor deposition in the apparatus shown in FIG. 2, a large-area platinum sulfide thin film was synthesized using the platinum complex (precursor, 30. 0 mg) prepared in Preparation Example 1. The Si/SiO₂ substrate and a container containing the precursor were placed in the deposition chamber. Heating was made by winding a thermal tape around the precursor side. For the substrate side, an external furnace was employed to adjust the sublimation and reaction temperature of the platinum complex to 100 to 600° C. at a vacuum condition of 800 mTorr or atmospheric pressure while argon (Ar) gas was introduced at 50 sccm. Argon gas was flowed as carrier gas (Ar) to carry out the thin film synthesis.

To analyze the basic properties of the platinum sulfide thin film thus prepared, electron microscopy, Raman spectroscopy, and X-ray photoelectron spectroscopy (XPS) were performed, and the results are shown in FIG. 3.

In FIG. 3, The upper panels are the electron microscopy images of the thin film prepared using the chemical vapor deposition method while the lower panels show the results of the Raman spectroscopy and XPS analysis.

As shown in FIG. 3, the electron microscopy analysis for the surface and cross section of the platinum sulfide thin film confirmed that the platinum sulfide thin film had a uniform but rough surface composed of particles of several hundred nanometers in size and a thickness of 39.2 nm. The X-ray photoelectron spectroscopy analysis showed peaks for Pt 4f7/2 and S 2p3/2 at 72.1 eV and 162.7 eV, respectively, indicating the predominant synthesis of PtS. In the Raman spectroscopic spectrum, a peak was observed at 331 cm⁻¹ corresponding to the A_{1g}¹ mode of PtS₂, implying that the synthesized thin film was a mixture of PtS and PtS₂.

### Example 3. Fabrication and Characterization of Optical Sensors

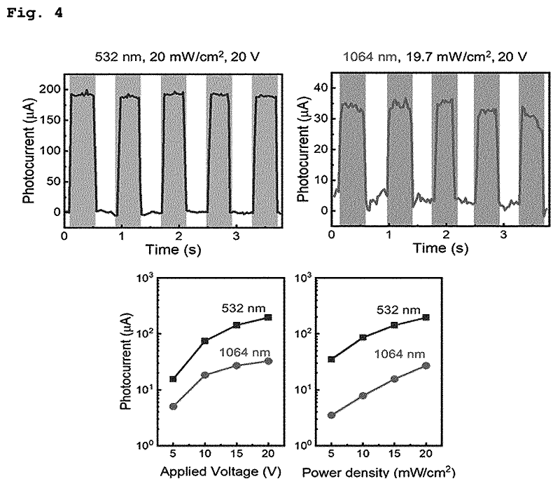

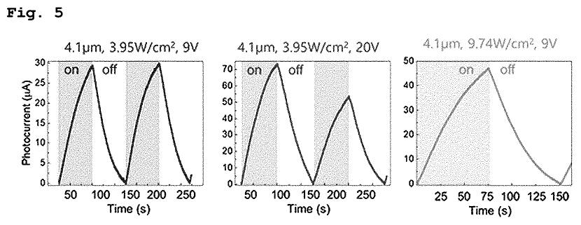

A platinum sulfide thin film synthesized on a substrate according to Example 2 was used to fabricate an optical sensor by depositing Cr/Au electrodes with thicknesses of 5 nm and 70 nm, respectively, using thermal evaporation. The two electrodes formed a channel with a length of 25 μm and a width of 500 μm. The fabricated sensor was tested by periodic irradiation with visible light (532 nm) and near-infrared (1064 nm) lasers while monitoring the generated photocurrent. The results showed that the generation and disappearance of photocurrent proceeded stably with periodic laser irradiation. When a 20 V bias voltage was applied and the sensor was irradiated with 532 nm and 1064 nm lasers at a power intensity of 20 mW, the photocurrents were 195 μA and 32.5 μA, respectively, as shown in FIG. 4.

To evaluate the mid-infrared detection capability of the optical sensor according to the present disclosure, the photocurrent generated by a 4.1 μm laser was measured under various conditions and the measurements are depicted in FIG. 5. As illustrated in FIG. 5, when a 4.1 μm laser with a power intensity of 3. 95 W/cm² was irradiated under a 9 V bias voltage, a periodic photocurrent of up to 30 μA was detected with a response and recovery time of approximately 5 minutes. This demonstrates the potential application of the sensor as a mid-infrared detector.

While the preferred embodiments of the present disclosure have been described in detail, the scope of the present disclosure is not limited thereto. Various modifications and improvements made by those skilled in the art using the basic concept defined in the following claims also fall within the scope of the present disclosure.

### INDUSTRIAL APPLICABILITY

The present disclosure relates to a platinum organometallic compound, a methods for fabricating a thin films using same, and a method for manufacturing an optical sensors using the same thin film and is industrially applicable.

1. An organometallic compound, represented by Chemical Formula A-1 or A-2. 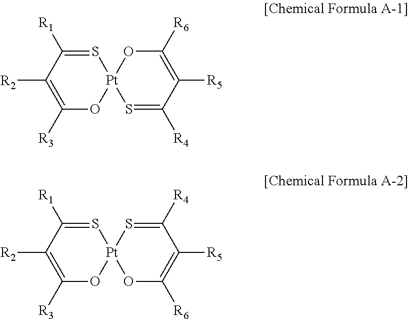
wherein,
R₁, R₃, R₄, and R₆, which are same or different, are each independently an any one selected from a linear, branched, or cyclic alkyl of C1-C10, and a linear, branched, or cyclic halogenated alkyl of C1-C10; and
R₂ and R₅, which are same or different, are each independently any one selected from a hydrogen atom, a deuterium atom, a linear, branched, or cyclic alkyl of C1-C10, and a linear, branched, or cyclic halogenated alkyl of C1-C10.

2. The organometallic compound of claim 1, wherein R₁, R₃, R₄, and R₆, which are same or different, are each independently a branched or cyclic alkyl of C1-C6.

3. The organometallic compound of claim 1, wherein R₁, R₃, R₄, and R₆, which are same or different, are each independently any one selected from CH₃, C₂H₅, CH(CH₃)₂, and C(CH₃)₃.

4. The organometallic compound of claim 1, wherein R₂ and R₅, which are same or different, are each independently any one selected from a hydrogen atom and a deuterium atom, CH₃, and C₂H₅.

5. The organometallic compound of claim 1, wherein the ligand containing R₁ to R₃ and the ligand containing R₄ to R₆ are identical to each other.

6. A method for fabricating a platinum thin film, a platinum oxide thin film, or a platinum sulfide thin film, using the organometallic compound of any one of claims 1 to 5 as a metal precursor.

7. The method of claim 6, wherein the platinum sulfide thin film is fabricated by a chemical vapor deposition (CVD) or atomic layer deposition method or a solution process.

8. The method of claim 6, wherein the platinum sulfide thin film comprises a platinum dichalcogenide compound.

9. A method for manufacturing the organometallic compound represented by Chemical Formula A-1 or A-2 of claim 1, wherein the organometallic compound represented by Chemical Formula A-1 or A-2 is prepared using a halogenated platinum compound represented by Compound D, a ketone compound represented by Compound C1, and a ketone compound represented by Compound C2 as reactants:
PtX₁X₂ [Compound D] 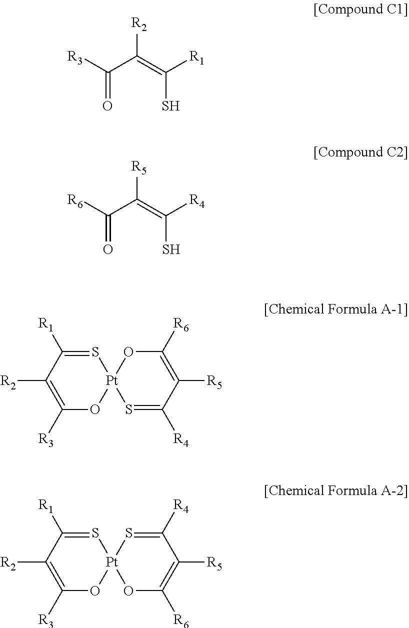
wherein,
X₁ and X₂ in Chemical Formula D are each independently a halogen element selected from F, Cl, Br, and I, and R₁ to R₆ in Compounds D, C1, and C2, and Chemical Formulas A-1 and A-2 are as defined in claim 1.

10. A method for manufacturing an optical sensor, the method comprising the steps of: a) introducing into a deposition chamber a substrate on which a platinum sulfide thin film is to be formed;
b) forming a platinum sulfide thin film on the substrate in the chamber by chemical vapor deposition or atomic layer deposition using a single-source precursor that bears both sulfur(S) and platinum (Pt) elements within a single molecule, where the platinum atom functions as a central metal and the sulfur atom is directly bonded to the platinum; and
c) forming a metal electrode in direct contact with the formed platinum sulfide thin film.

11. The method of claim 10, wherein the platinum sulfide thin film in step b) has a thickness of 5 nm to 0.5 μm.

12. The method of claim 10, further comprising a step of subjecting the substrate to hydrophilic treatment before step a).

13. The method of claim 10, wherein the substrate is made of any one selected from silicon (Si), SiO₂, SiO₂/Si, sapphire, glass, quartz, flexible glass (Willow glass), and plastics.

14. The method of claim 10, wherein the single-source precursor undergoes sublimation or evaporation within the deposition chamber containing the substrate, or the single-source precursor is sublimated or evaporated in a separate chamber or heating apparatus and is then transferred to the deposition chamber containing the substrate.

15. The method of claim 10, wherein the platinum sulfide thin film in step b) comprises a component selected from PtS, PtS₂, and mixtures thereof.

16. The method of claim 10, wherein the single-source precursor used in step b) comprises an organometallic compound represented by any one of Chemical Formulas A-1, A-2, and B: 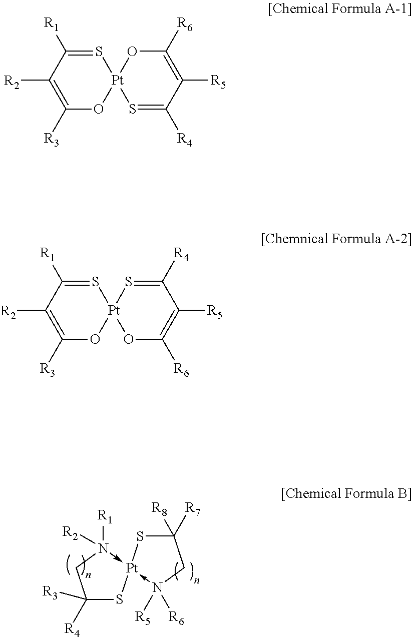
wherein,
R₁, R₃, R₄, and R₆ in Chemical Formulas A-1 and A-2, which are same or different, are each independently any one selected from a linear, branched, or cyclic alkyl of C1-C10 and a linear, branched, or cyclic halogenated alkyl of C1-C10,
R₂ and R₅, which are same or different, are each independently any one selected from a hydrogen atom, a deuterium atom, a linear, branched, or cyclic alkyl of C1-C10, and a linear, branched, or cyclic halogenated alkyl of C1-C10,
R₁ to R₈ in Chemical Formula B, which are same or different, are each independently any one selected from a hydrogen atom, a deuterium atom, a linear, branched, or cyclic alkyl of C1-C10, and a linear, branched, or cyclic halogenated alkyl of C1-C10,
n is an integer of 1 to 3.

17. The method of claim 16, wherein, in Chemical Formulas A-1 and A-2, R₁, R₃, R₄, and R₆ are each independently any one selected from CH₃, C₂H₅, CH(CH₃)₂, and C(CH₃)₃, or R₂ and R₅ are each independently any one selected from hydrogen atom, a deuterium atom, CHs, and C2H.

18. The method of claim 16, wherein the ligand containing R₁ to R₃ and the ligand containing R₄ to R₆ in Chemical Formulas A-1 and A-2 are identical to each other.

19. An optical sensor capable of detecting mid-infrared radiation, manufactured by the method of any one of claims 10 to 18.
